(19) United States
(12) Patent Application Publication
(10) Pub. No.: US 2013/0058155 A1
(43) Pub. Date: Mar. 7, 2013

(54) SRAM DIMENSIONED TO PROVIDE BETA RATIO SUPPORTING READ STABILITY AND REDUCED WRITE TIME

(71) Applicants: Olivier Callen, Meylan (FR); Anuj Grover, New Delhi (IN); Tanmoy Roy, Greater Noida (IN)

(72) Inventors: Olivier Callen, Meylan (FR); Anuj Grover, New Delhi (IN); Tanmoy Roy, Greater Noida (IN)

(73) Assignees: STMICROELECTRONICS PVT LTD, Greater Noida (IN); STMICROELECTRONICS (CROLLES 2) SAS, Crolles Cedex (FR)

(21) Appl. No.: 13/594,064

(22) Filed: Aug. 24, 2012

(30) Foreign Application Priority Data
Sep. 2, 2011 (FR) 1157796

(51) Int. Cl. G11C 11/00

(52) U.S. Cl. 365/154

(57) ABSTRACT

A 6T SRAM includes two inverters connected in antiparallel, and two access transistors, each connected between a bit line and a common node of the inverters. Each inverter includes a pullup transistor and a pulldown transistor. A product formed by a ratio of the pulldown transistor gate width to the access transistor gate width multiplied by a ratio of the access transistor gate length to the pulldown transistor gate length is smaller than one. Furthermore, the pullup transistor gate width is greater than or equal to the pulldown transistor gate width.

### PRIORITY CLAIM

The present application claims priority from French Application for Patent No. 1157796 filed Sep. 2, 2011, the disclosure of which is hereby incorporated by reference.

### TECHNICAL FIELD

The present disclosure relates to microelectronics, and more specifically to the forming of SRAM-type memories, formed on substrates of a semiconductor material, and especially of silicon type. The present disclosure more specifically relates to memory cells having a read access circuit separate from the write access circuit and thus enabling to optimize their write performance.

### BACKGROUND

Generally, electronic memories are formed of a set of elementary cells, designed to contain binary data. Such cells are arranged in an array, in a given number of lines and columns. Each SRAM contains a “data” bit, the bits being themselves organized in “words”, the external read and write circuits taking part in the definition of this organization. The number of words per line is designated as “mux”, as a reference to data multiplexing.

Conventionally, memory cells are formed by an assembly of different transistors, typically insulated-gate field-effect transistors (MOSFET).

Conventionally, and as illustrated in FIG. 1, a memory cell 1 comprises an assembly of two inverters 2, 12 connected in antiparallel to form a bistable system, that is, a system having two stable operating points, and the transition from one to the other can only be obtained by an external action, typically ensured by the write circuit. Each inverter 2, 12 comprises a transistor 5, 15 of connection to the high level supply node, the transistor typically of P-channel MOS type, in series with a transistor 6, 16 of connection to the low level supply node, the transistor typically of N-channel MOS type.

Gates 7, 8, 17, 18 of these two transistors are interconnected and connected to midpoint 19, 9 of the other inverter.

The two inverters 2, 12 are controlled by the connection of gates 7, 8, 17, 18 of their transistors to opposite signals originating from bit lines 20, 21. This control is performed via transistors 22, 23 having their gate 25, 26 controlled by a word line 29, which is powered when the cell belongs to the word where the writing must be performed.

All six transistors 5, 15, 6, 16, 25, 26 thus brought together define a so-called “6T” cell having a conventional design.

### SUMMARY

Given the increase in electronic circuit operating frequencies, and in particular in memory access frequencies, the performance of memory cells needs to be optimized. At the same time, in certain self-contained devices, powered by a limited power source and delivering a voltage which decreases as power is being consumed, there also is a need for memories having as stable a state as possible, despite a decrease in the power supply voltage. Further, given the decrease in electronic component sizes, it is also desirable to do away with the constraints associated with the sizing of the different elements forming a memory, while remaining compatible, as much as possible, with the above-mentioned needs. Finally, to minimize manufacturing costs, it is desirable to limit the number of manufacturing steps by using steps common to all the other devices used in the circuit for the SRAM cell.

To achieve these objects, the present invention provides a SRAM having an optimized write margin (meant as being the capacity to see the bistable state modified), write time, and minimum data retention voltage, independently from the constraints associated with the reading and this, without adding specific manufacturing steps.

Typically, the independence from reading-related constraints may be ensured by the creation of a high-impedance read circuit connected to one, to the other, or to both mid-points of the inverters.

Thus, an aspect of the present invention provides a SRAM, comprising a plurality of 6T-type memory cells, based on six insulated gate field-effect transistors, each cell comprising two inverters connected in antiparallel and two different write and read access circuits, said write circuits comprising two access transistors, each connected to a bit line dedicated to the writing and to a common node of the different inverters, and having their gates connected to a word line, each inverter comprising a transistor of connection to the high level and a transistor of connection to the low level, wherein the gate width of the transistor of connection to the low level is strictly smaller than the gate width of the write access transistors, and the gate width of the transistors of connection to the high level is greater than or equal to the gate width of the transistors of connection to the low level.

According to an embodiment the ratio of the gate width of the transistors of connection to the low level (W_{PD}), divided by the gate width of the write access transistors (W_{PG}) multiplied by the ratio of the gate length of the write access transistors (L_{PG}), divided by the gate width of the transistors of connection to the low level (L_{PD}) of the memory cell is smaller than 0.7.

This ratio, called “beta ratio” of the memory cell hereinafter, combines the width and length features of write access transistors and of transistors of connection to the low level. It is then possible to compensate for a disadvantageous ratio on the gate widths with an adapted ratio on the gate lengths, and conversely, to obtain the desired value by providing a good read stability and a write time to the memory cell.

According to an embodiment, the ratio of the gate width of the transistors of connection to the low level to the gate width of the write access transistors ranges between 0.3 and 0.7, and preferably between 0.3 and 0.5.

According to another embodiment, the ratio of the gate width of the transistors of connection to the high level to the gate width of the transistors of connection to the low level ranges between 1 and 2. In a first case depending on the technology used, this ratio may range between 1 and 1.6, preferably between 1.1 and 1.5, or even close to 1.3. In another case corresponding to another technological choice, this ratio may range between 1.4 and 2, preferably between 1.5 and 1.9, or even close to 1.7.

### BRIEF DESCRIPTION OF THE DRAWINGS

The implementation and other features and advantages of the present invention will be discussed in detail in the following non-limiting description of a specific embodiment in connection with the accompanying drawings, wherein:

FIG. 1, previously described, schematically shows a conventional SRAM 6T cell; and

FIG. 2 is a top view of a 6T cell layout according to an embodiment.

The examples given hereafter are provided as a non-limiting illustration only. The different dimensions and proportions are only given to provide a better understanding of the present invention, and may have been exaggerated and differ from reality to ease the understanding of the present invention.

### DETAILED DESCRIPTION

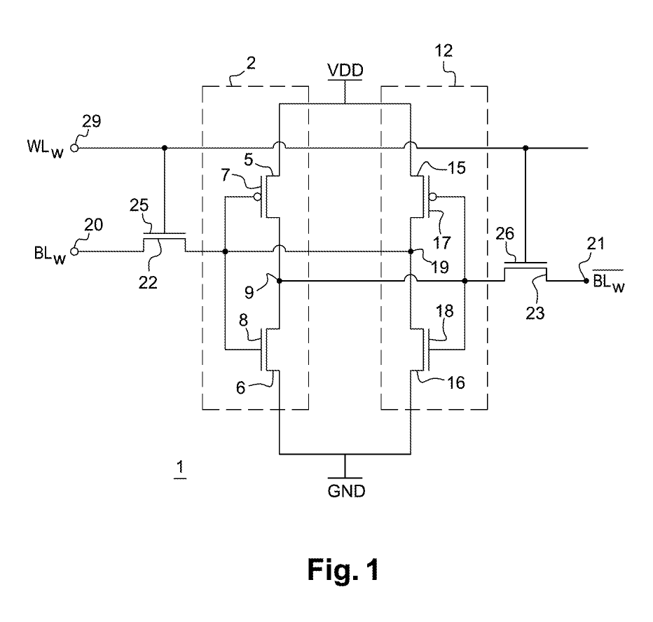

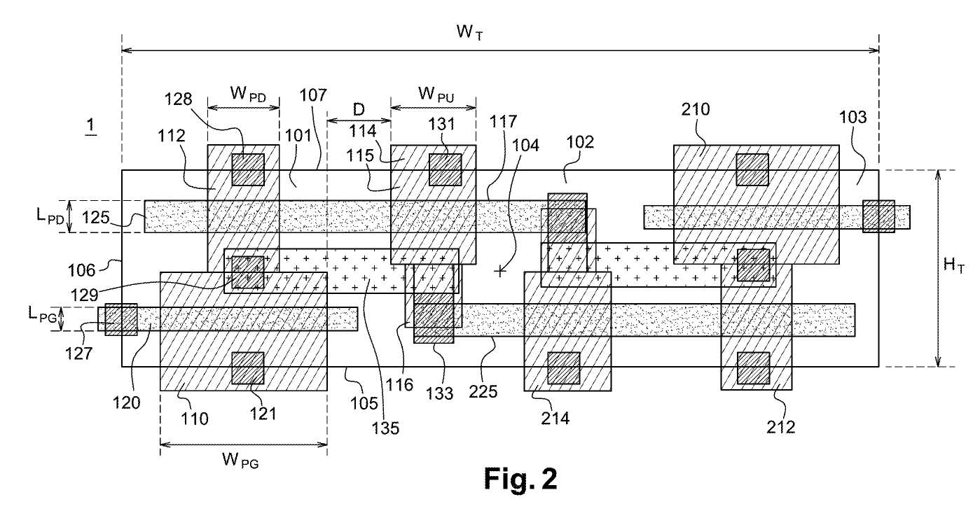

The layout illustrated in FIG. 2 illustrates an embodiment of the different active areas of a 6T cell corresponding to the electric diagram of FIG. 1. Only the two inverters forming the bistable storage element and the two write access transistors have thus been shown in this cell. The read circuit(s) are conventionally formed by an additional assembly of two or four transistors which may be formed independently from certain aspects of the present invention.

In the form illustrated in FIG. 2, the 6T cell 1 substantially comprises three aligned sectors 101, 102, 103, having a central symmetry point 104. Lateral sector 101 comprises a first active area 110 made in the silicon substrate, to form the source and the drain of a write access transistor, also called “pass-gate” transistor 22. Active area 110 is adjacent to a second active area 112 which forms the source and the drain of one of the transistors of one of the inverters, and more specifically of the NMOS transistor of connection to the low state, also called “pull-down” transistor 6.

Central sector 102 of the 6T cell comprises an active area 114 which forms the source and the drain of the other transistor of the inverter, that is, the transistor of connection to the high state, also called “pull-up” transistor 5. Active area 114, which forms a PMOS-type transistor, comprises two different regions. A first region 115 is located in front of the pull-down transistor, and receives gate 117. Region 115 has a width W_{PU.}

A second region 116 is located in front of the pass-gate transistor. It forms an active area 116 of smaller width, to keep a sufficient distance from the active area of the pass-gate transistor, and enable the implantation of shallow insulating trenches (STI, for Shallow Trench Isolation) of proper dimensions.

The other active areas 210, 212, 214 present in the 6T cell are arranged symmetrically with respect to central point 104, to form the other inverter and its access transistor.

The pull-down and pass-gate transistors present in sectors 101 and 103 are formed with the transistor type (N or P) providing the best electric conductivity, to maximize the charge transfer efficiency through the pass-gate transistor. The pull-up transistor is formed with the complementary type (respectively P or N) so that transistors 5 and 6 on the one hand, and transistors 15 and 16 on the other hand, form inverters. Conventionally, the transistors (pass-gate, pull-down) of sectors 101 and 103 are of type N and those of sector 102 (pull-up) are of type P. The transistors types indicated in FIG. 1 correspond to this conventional configuration.

It should be noted that the general layout of the memory cell would not be modified on the assumption that, for reasons of electric conductivity, the pass-gate and pull-down transistors are of type P and the pull-up transistors are of type N. Only the connections to the high (Vdd) and low (Gnd) points should be inverted.

At the upper level, the silicon substrate receives gate structures laid on the active areas. Such gate structures may be for example formed by a stacking of oxide and of polysilicon.

Gate structure 120 is laid on active area 110, to form gate 25 of pass-gate transistor 22, extends all the way to cell limit 105, and receives at this level a contact pillar 121, enabling the connection to write bit line BL_{W}. Active areas 112, 114 of the pull-down and pull-up transistors share another gate structure 125, which thus covers these two areas.

Active area 110 of the pass-gate transistor also comprises a contact pillar 127 located at cell limit 106 and intended to be connected to write word line WL_{W}. Active area 112 of pull-down transistor 6 comprises at cell limit 107 a contact pillar 128 conventionally intended to be connected to the low potential node (or GND). In their contact regions, active areas 110, 112 of pass-gate transistor 22 and of pull-down transistor 6 comprises a common pillar 129 astride the two areas 112, 110.

Pull-up transistor 5 comprises at cell limit 107 a contact pillar 131 conventionally connected to the high potential node (or V_{DD}). Narrower region 116 of the pull-up transistor also comprises a larger contact pillar 133, which is partly in contact with active area 116 and partly in contact with layer 225 forming the common gate structure of the pull-up and pull-down transistors of the other cell inverter.

Contact pillar 133 is connected, at a higher metallization level, to pillar 129 forming the common node of pull-down transistor 6 and pass-gate transistor 22, via a metal track 135.

The junctions of active areas 110 and 112 between the gates of the pass-gate and pull-down transistors as well as those of their symmetrical areas 210 and 212, define two internal nodes (IN). The injection of current in the memory cell from the bit line into the internal node is a function of the widths of the active areas as well as of the gate widths of the pass-gate and pull-down transistors. The ratio of voltage V_{IN} between the internal node and the drain of the pull-down transistor to voltage V_{BL} between the source of the pass-gate transistor connected to the bit line and the internal node defines analytic equation:

$$\frac{{V}_{IN}}{{V}_{BL}} = \frac{1}{1 + \frac{{R}_{PG}}{{R}_{PD}}}$$

where R_{PG} is the resistance of the contact between the gate of the pass-gate transistor and active area 110, and R_{PD} is the resistance of the contact between the gate of the pull-down transistor and active area 112. Such resistances are a function of width W_{PG} and W_{PD} of active areas 110 and 112, of a parameter called α′ hereinafter, and of the gate widths of pass-gate transistor L_{PG} and pull-down transistor L_{PD}. The ratio of the two resistances can be expressed as follows:

$$\frac{{R}_{PG}}{{R}_{PD}} = \frac{{W}_{PD}}{{W}_{PG}} \frac{{L}_{PG}}{{L}_{PD}} [ 1 + {{α}^{′} ( {L}_{PG} - {L}_{PD} )}^{2} ]$$

Reference is made herein to ratio

$$\frac{{W}_{PD}}{{W}_{PG}} \frac{{L}_{PG}}{{L}_{PD}}$$

as the “beta ratio”, while the second term [1+α′(L_{PG}−L_{PD})²] is called the “gamma” factor. The “beta ratio” is a usual indicator for assessing the performance of SRAM cells.

The Applicants provide a structure enabling to keep the properties of stability of the memory cell while optimizing the memory cell write time by selecting unusual pass-gate, pull-down, and pull-up gate widths, which may even result in “beta ratios” that can be smaller than 1 and on the order of 0.5.

As illustrated in FIG. 2, width W_{PG} of active area 110 of the pass-gate transistor is greater than width W_{PD} of the pull-down transistor. This enables, on the one hand, to maximize the transmission of the potential of bit line BL_{W} to the internal node of the memory cell, to maximize the write margin, thus enabling to operate at lower voltage; and on the other hand to maximize the current transiting from write bit line BL_{W}, to increase the write time. Preferably, width W_{PG} of the pass-gate transistor will thus be desired to be increased to a maximum. However, this increase is in practice limited by the fact that the interval between width W_{PG} of the pass-gate transistor and width of the pull-down transistor W_{PD} cannot be too large. Indeed, for technological reasons, it is preferable to avoid layouts having very close direction variations for border areas of the transistors formed by shallow trenches (or STI).

Similarly, width W_{PU} of the pull-up transistor cannot decrease below a given limit depending on the “technological node”, for reasons linked to the repeatability of the dopant implantation process to form active areas. This limit is on the order of some hundred nanometers for the so-called “65 nm” technological node.

It is also possible to design SRAM cells having different dimensional constraints relative to widths W_{PG} and W_{PD} of active areas 110 and 112, but in which the gate widths of the pass-gate and pull-down transistors are selected to obtain a “beta ratio” smaller than 0.7. In such a configuration, the value of the “beta ratio” is adjusted by means of an adapted sizing of widths L_{PG} and L_{PD} of the gates of the pass-gate and pull-down transistors.

According to a specific embodiment, ratio a between these two widths (W_{PD}/W_{PG}) is thus smaller than 1, and close to 0.3.

Such a sizing of widths W_{PG} and W_{PD} of active areas 110 and 112 makes the memory cell very unstable. The provided advantage is that it can be written into rapidly when the pass-gate transistors are in the on state. However, it is also necessary to make the memory cell very stable when it retains information, that is, when the pass-gate transistors are in the off state.

For this purpose, the ratio of width W_{PU} of the pull-up transistor to width W_{PD} of the pull-down transistor is selected so that current Iₒₙ is as close as possible in the two transistors.

Thereby, on the one hand, the bistable state switching time is decreased, which results in a decrease of the time necessary for the writing, or write time. On the other hand, the stability in case of a lowering of the power supply voltage, which criterion is generally called “retention noise margin”, is increased.

For this purpose, width W_{PU} of the pull-up transistor is selected to be greater than or equal to width W_{PD} of the pull-down transistor, with a ratio between these two widths which is selected according to the conductivity of the transistor types, conventionally linked to the nature and to the concentration of the dopants which are used for these two transistors, as well as to the mobility of the charge carriers and to other physical parameters.

In practice, the selection of the transistor type, and thus of the conductivity ratio, may be imposed by the design of the transistors of the logic gates of the other circuits associated with the memory, which are preferably formed during common steps.

In other words, according to the technological choices made for the components comprising the memory, the optimal ratio between W_{PU} and W_{PD} can be optimized. On the assumption of the use of a minimum number of manufacturing steps implying the use of a single family of transistors (for example, “Low-V_{T}”), a value on the order of 1.7±0.3 will be considered as optimal in a technology of “32 nm CMOS Low Power (LP)” type. Still as an example and on the assumption of the use of a single family of transistors, a value on the order of 1.3±0.3 will be considered as optimal in a technology of “32 nm CMOS High Performance (HP)” type implementing stress effects.

For the sizing of the different active areas, account will also be taken of the fact that the pull-up transistor must not come too close to the pass-gate transistor, and that a distance D between the two corresponding active areas which is sufficient for the implantation of the insulating trenches must be kept.

As an example, in the context of a memory formed according to the 32-nanometer technological node, height H_{T} of a 6T cell is on the order of 250 nanometers, for a width W_{T} on the order of 900 nanometers. Half the width difference ½.(W_{PG}−W_{PD}) between the pass-gate transistor and the pull-down transistor is on the order of a few tens of nanometers, and typically from 70 to 80 nanometers. Distance D separating the nodes closest to active areas 110, 114 of the pass-gate and pull-up transistors is of the same order. Of course, such distances and other dimensions are not limiting, they correspond to a given technology, and may of course be declined according to the used technological node and to other external constraints.

As appears from the foregoing, the memory cell thus formed has the combined advantage of improving the write capacity of the cell, which translates as a decrease in the time required for the writing, and of increasing the write margin. Similarly, the bistable structure formed by the two inverters associated in the 6T cell has a better stability in case of a lowering of the power supply voltage, which criterion is generally called “retention noise margin”.

Of course, the present invention is likely to have various alterations, modifications, and improvements which will readily occur to those skilled in the art. Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An SRAM, comprising:
a plurality of 6T-type memory cells, each cell comprising two inverters connected in antiparallel, and access circuits comprising two access transistors, each access transistor connected between a bit line and a common node of the different inverters, and having a gate connected to a word line, each inverter comprising a first transistor coupled between the common node and a high level supply node and a second transistor coupled between the common node and a low level supply node,
wherein a product formed by a ratio of the gate width of the second transistors to the gate width of the access transistors multiplied by a ratio of the gate length of the access transistors to the gate length of the second transistors is smaller than one.

2. The SRAM of claim 1, wherein the gate width of the first transistors is greater than or equal to the gate width of the second transistors.

3. The SRAM of claim 1, wherein said product is smaller than 0.7.

4. The SRAM of claim 1, wherein a ratio of the gate width of the second transistors to the gate width of the access transistors is between 0.3 and 0.7.

5. The SRAM of claim 1, wherein a ratio of the gate width of the second transistors to the gate width of the access transistors is between 0.3 and 0.5.

6. The SRAM of claim 1, wherein a ratio of the gate width of the first transistors to the gate width of the second transistors is between 1 and 2.

7. The SRAM of claim 1, wherein a ratio of the gate width of the first transistors to the gate width of the second transistors is between 1 and 1.6.

8. The SRAM of claim 1, wherein a ratio of the gate width of the first transistors to the gate width of the second transistors is between 1.1 and 1.5.

9. The SRAM of claim 1, wherein a ratio of the gate width of the first transistors to the gate width of the second transistors is between 1.4 and 2.

10. The SRAM of claim 1, wherein a ratio of the gate width of the first transistors to the gate width of the second transistors is between 1.5 and 1.9.

11. An SRAM cell, comprising:
a first inverter circuit including a first pullup transistor and a first pulldown transistor;
a second inverter circuit including a second pullup transistor and a second pulldown transistor;
wherein the first and second inverter are coupled to form a bistable circuit element;
a first access transistor coupled to an input of the first inverter circuit;
a second access transistor coupled to an input of the second inverter circuit;
wherein a product formed by a ratio of the gate width of the first pulldown transistor to the gate width of the first access transistor multiplied by a ratio of the gate length of the first access transistor to the gate length of the first pulldown transistor is smaller than one.

12. The SRAM cell of claim 11, wherein a gate width of the first pullup transistor is greater than or equal to the gate width of the first pulldown transistor.

13. The SRAM cell of claim 11, wherein a gate width of the first pullup transistor is greater than the gate width of the first pulldown transistor.

14. The SRAM cell of claim 13, wherein a ratio of the gate width of the first pullup transistor to the gate width of the first pulldown transistor is between 1.1 and 1.5.

15. The SRAM cell of claim 13, wherein a ratio of the gate width of the first pullup transistor to the gate width of the first pulldown transistor is between 1.4 and 2.

16. The SRAM cell of claim 13, wherein a ratio of the gate width of the first pullup transistor to the gate width of the first pulldown transistor is between 1.5 and 1.9.

17. The SRAM cell of claim 11, wherein said product is smaller than 0.7.

18. The SRAM cell of claim 11, wherein a ratio of the gate width of the first pulldown transistor to the gate width of the first access transistor is between 0.3 and 0.7.
